(19) United States
(12) Patent Application Publication
(10) Pub. No.: US 2026/0203481 A1
(43) Pub. Date: Jul. 16, 2026

(54) Resource Utilization Model for Programmable Integrated Circuit Devices

(71) Applicant: Altera Corporation, San Jose, CA (US)

(72) Inventors: Babette Van Antwerpen, Mountain View, CA (US); Selvin Quadros, San Jose, CA (US); Asad Ghaffar, Toronto (CA); Mahesh Iyer, Fremont, CA (US)

(21) Appl. No.: 19/565,511

(22) Filed: Mar. 12, 2026

(51) Int. Cl. G06F 30/27; G06F 9/50; G06N 20/00

(52) U.S. Cl. CPC G06F 30/27; G06F 9/50; G06N 20/00

(57) ABSTRACT

In an aspect, a system may include a programmable integrated circuit device and a data processing system. The data processing system may be configured to execute instructions to receive a system design for a programmable integrated circuit device and generate a technology-mapped netlist based on synthesizing the system design. The data processing system may include a resource utilization model configured to determine a predicted resource utilization for the integrated circuit system design based on the technology-mapped netlist. The data processing system also may generate a resource utilization report based on the predicted resource utilization.

### BACKGROUND

The present disclosure relates generally to integrated circuits and, more specifically, to systems and methods for predicting resource utilization in programmable integrated circuit devices.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Modern electronics, such as computers, portable devices, network routers, data centers, Internet-connected appliances, and the like, tend to include at least one integrated circuit device. Integrated circuit devices may take on a variety of forms, including processors, memory devices, and programmable integrated circuit devices, to name only a few examples. Programmable integrated circuit devices, such as field programmable gate arrays (FPGAs), may include a programmable fabric of logic that a designer may program and reprogram after manufacturing with system designs to provide various functionality. Because programmable integrated circuit devices have finite resources, it may be desirable to predict or estimate resource usage as part of a configuration process for programming the programmable integrated circuit devices. However, predicting resource utilization for programmable integrated circuit devices may be time and resource intensive.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device;

FIG. 2 is a block diagram of an example of the integrated circuit device of FIG. 1;

FIG. 3 is a diagram of a data processing system with design software, including a resource utilization model, for configuring a programmable integrated circuit device, such as the integrated circuit devices of FIG. 1 and FIG. 2;

FIG. 4 is an example of a design implementation flow for configuring the programmable integrated circuit device of FIG. 3;

FIG. 5 is a graph depicting time elapsed during compilation and synthesis steps compared to the time elapsed in the fitter steps in the design implementation flow of FIG. 4;

FIG. 6 is a flowchart illustrating a method of training the resource utilization model of FIG. 3;

FIG. 7 is a flowchart illustrating steps that the model training system of FIG. 3 may use for generating an expanded set of system designs as described with reference to the method of FIG. 6;

FIG. 8 is a flowchart illustrating a method for the design software of FIG. 3 to generate a predicted resource utilization report after a synthesis step in the design implementation flow of FIG. 4;

FIG. 9 is an example of a predicted resource utilization report that may be generated by the resource utilization model according to the method illustrated in FIG. 8; and

FIG. 10 is a block diagram of a data processing system that may incorporate the systems and methods of this disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

As mentioned, programmable integrated circuit devices may include a programmable fabric that a designer (e.g., anyone configuring or reconfiguring the programmable logic device) may interact with to cause the programmable integrated circuit device to perform a desired operation. In some cases, a designer may describe a system design for a programmable integrated circuit device using Register-Transfer Level (RTL) code. For example, the designer may provide a system design (e.g., a user design, a digital hardware design, a configuration, a circuit design) in a hardware description language (HDL) file using RTL code to define a behavior of a programmable integrated circuit device. The designer may use design software to generate a configuration file based on the system design, and the configuration file may be applied to the programmable integrated circuit device to configure and/or reconfigure the programmable fabric of the programmable integrated circuit device.

In some aspects, the design software may generate the configuration file based on a design implementation flow. For example, a first stage of the design implementation flow may include synthesis steps. The synthesis steps may include the design software generating a circuit graph of primitives (e.g., a circuit graph of field programmable gate array (FPGA) primitives in the case of an FPGA, a circuit graph of primitive gates in the case of an application-specific integrated circuit (ASIC)). The synthesis steps also may include the design software generating a technology-mapped netlist (e.g., a synthesis netlist, a gate-level netlist) for a programmable integrated circuit device based on the circuit graph of primitives. The design software may optimize and translate the circuit graph of primitives into programmable logic circuit elements, including lookup tables (LUTs) and flip-flops. The design software also may inference programmable logic blocks (e.g., digital signal processing (DSP) blocks and/or random access memory (RAM) blocks) at this stage. A second stage of the design implementation flow may include fitting steps for fitting the technology-mapped netlist onto the programmable integrated circuit device. In some aspects, the design software may fit the technology-mapped netlist onto the programmable integrated circuit device based on resources within the programmable integrated circuit device. More specifically, the design software may place and/or cluster logic on the programable integrated circuit device, perform clock allocation, routing, retiming, and/or apply a physical configuration onto the programable integrated circuit device. The design software may do so based on the resources of the programmable integrated circuit device, which may include adaptive logic modules (ALMs), logic array blocks (LABs) (e.g., collections of ALMs), routing and interconnect resources, hyperflex registers, programmable logic blocks, and other types of circuitry.

As may be appreciated, a designer may benefit from understanding resource allocation within the programmable integrated circuit device throughout this multi-stage design implementation flow. However, some design software systems may generate a resource utilization report at the end of the design implementation flow (e.g., after the fitting stage). The resource utilization report may include indications of resource metrics corresponding to resources used by the system design. For example, the resource utilization report may include an ALM count, a total percentage of available ALMs, a dedicated number of logic registers, a number of programmable logic circuit elements (e.g., LUTs, flip-flops), and/or other suitable indications as to resource usage on the programmable integrated circuit device. The resource utilization report may enable the designer to determine how much programmable logic the system design occupies on the programmable integrated circuit device. As a result, the designer may use the resource utilization report as an indication of whether additional logic (e.g., additional operations or functionalities) may be included in the system design or if they need to select a different device that meets their application’s needs. In some cases, the resource utilization report may provide an indication to the designer about the compatibility of a particular programmable integrated circuit device for the system design. For example, if the system design includes a significant resource utilization (e.g., 80% resource utilization, 90% resource utilization, 95% resource utilization), then the designer may determine that the system design should be implemented on a larger programmable integrated circuit device with more significant resources.

As may be appreciated, it may be difficult to estimate resource utilization before completing the design implementation flow. More specifically, it may be difficult to determine resource utilization before the fitting steps where the logic in the technology-mapped netlist is fit onto the programmable integrated circuit device. Thus, in some systems, the design software may generate a resource utilization report at the end of the fitting steps (e.g., the second stage). However, as will be discussed throughout this disclosure, the fitting step may demand significant timing resources relative to the synthesis steps (e.g., the first stage).

With this in mind, the present disclosure provides systems and methods for predicting resource utilization in programmable integrated circuit devices without going through the compute-intensive fitting stage. More specifically, the present disclosure provides a resource utilization model that may be trained to predict resource utilization during the design implementation flow. In aspects of the present disclosure, the resource utilization model may be any suitable type of artificial intelligence (AI) model, such as an eXtreme Gradient Boosting (XGBoost) model. The resource utilization model may be trained to predict one or more resource utilization metrics based on a technology-mapped netlist generated at the synthesis stage of the design implementation flow. In other words, the disclosed the resource utilization model may generate a predicted resource utilization report before the fitting step in the design implementation flow. As such, the disclosed resource utilization model may provide designers with an early and time-efficient indication of an expected resource utilization of a system design for a programmable integrated circuit device. The designer may use this predicted resource utilization report to evaluate the system design and/or the programmable integrated circuit device that the system design may be implemented on.

In aspects of the present disclosure, the resource utilization model may be trained to predict resource utilization based on features of the system design included in the technology-mapped netlist, such as aggregate counts of programmable logic circuit elements (LUTs, flip-flops) and fine-grained counts of LUTs based on the number of inputs that the LUTs are configured to receive. In some aspects, the resource utilization model may consider additional primitive counts, including programmable logic blocks (e.g., block DSP, block RAM), input output (I/O) pins, and/or carry change elements (e.g., dedicated routing resources). Further still, in some aspects, the resource utilization model may consider structural patterns and connectivity in the technology-mapped netlist, such as single-fan-out pairs and varying length fan-out pairs. In some aspects, the resource utilization model may be trained and/or fine-tuned for different types of programmable integrated circuit types. For example, the resource utilization model may be trained to determine resource utilization based on programmable integrated circuit device features, such as device families, available resources, optimization settings, and the like. As will be discussed throughout this disclosure, feature engineering may be used to identify and train the resource utilization model on the most relevant features for predicting resource utilization. As may be appreciated, training the resource utilization model in this manner may demand significant training data. Aspects of the present disclosure include systems and methods for generating artificial training data (e.g., synthetic system designs) based on combining design hierarchies from an available set of programmable integrated circuit device system designs (e.g., actual training data). As will be discussed throughout this disclosure, training the resource utilization model based on this training data and feature engineering may result in a lightweight model (e.g., less than or equal to five megabytes) that may provide an accurate and time-efficient predicted resource utilization report (e.g., around or better than 95% accuracy with negligible inference time relative to the design implementation flow) after the synthesis stage in the design implementation flow.

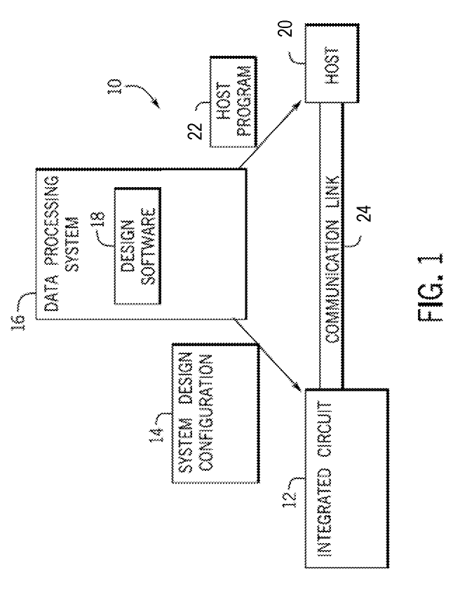

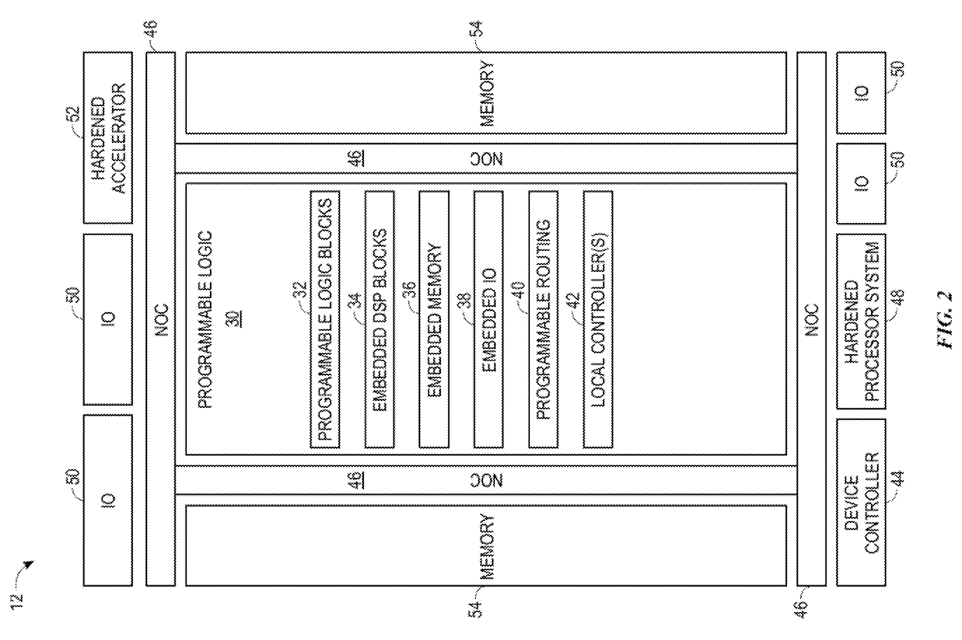

With the foregoing in mind, FIGS. 1 and 2 provide a background on the programmable integrated circuit devices. For example, FIG. 1 illustrates a block diagram of a system 10 that may be used to program an integrated circuit device 12, such as an FPGA (e.g., Agilex™, Stratix®, Arria®, MAX®, or Cyclone® devices by Altera® Corporation), with such a system design using a system design configuration 14. Note that, while this disclosure largely refers to the integrated circuit device 12 as being a programmable integrated circuit device, such as an FPGA, in some embodiments, the integrated circuit device 12 may also include a one-time programmable device or structured application specific integrated circuit (ASIC), such as an Altera® eASIC™ device by Altera® Corporation. In other examples, the integrated circuit device 12 may be any suitable integrated circuit that is manufactured to have a particular system design with circuitry to perform desired data processing operations. The integrated circuit device 12 may be a single monolithic integrated circuit or a multi-die system of integrated circuits. The integrated circuit device 12 may include a single integrated circuit, multiple integrated circuits in a package, or multiple integrated circuits in multiple packages communicating remotely (e.g., via wires, via traces) and may be referred to as an integrated circuit device or an integrated circuit system whether formed from a single integrated circuit or multiple integrated circuits in a package.

A designer may desire to implement the system design 14 (sometimes referred to as a circuit design or configuration) to perform a wide variety of possible operations on the integrated circuit device 12. In some cases, the designer may specify a high-level program to be implemented, such as an OPENCL® program that may enable the designer to more efficiently and easily provide programming instructions to configure a set of programmable logic cells for the integrated circuit device 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

In a configuration mode of the integrated circuit device 12, a designer may use a data processing system 16 (e.g., a computer including a data processing system having a processor and memory or storage) to implement high-level designs (e.g., a system design, a user design) using design software 18 (e.g., executable instructions stored in a tangible, non-transitory, computer-readable medium such as the memory or storage of the data processing system 16), such as a version of Altera® Quartus® by Altera Corporation. The data processing system 16 may use the design software 18, which may include a compiler (e.g., an RTL compiler) for converting the high-level program into a lower-level description (e.g., a configuration program, a bitstream) as the system design configuration 14. The compiler may provide machine-readable instructions representative of the high-level program to a host 22 and the system design configuration 14 to the integrated circuit device 12. Additionally or alternatively, the compiler may include an RTL-to-RTL compiler that compiles RTL as previously noted or the RTL-to-RTL compiler may be separate from the compiler. As will be discussed in more detail below, the system design configuration 14 may include an application program that may be associated with one or more functions. In particular, the application program may be configured to run the one or more functions on the data processing system 16. For example, the data processing system 16 may execute the application program.

Additionally or alternatively, the host 22 running the host program 24 may control or implement the system design configuration 14 onto the integrated circuit device 12. For example, the host 22 may communicate instructions from the host program 24 to the integrated circuit device 12 via a communications link 26 that may include, for example, direct memory access (DMA) communications or peripheral component interconnect express (PCIe) communications. The designer may use the design software 18 to generate and/or to specify a low-level program, using low-level tools such as the low-level hardware description languages described above. Further, in some embodiments, the system 10 may be implemented without a separate host 22 or host program 24. Thus, embodiments described herein are intended to be illustrative and not limiting.

The integrated circuit device 12 may take any suitable form that may implement the system design configuration 14. In one example shown in FIG. 2, the integrated circuit device 12 may include programmable logic circuitry 30, which may include a two-dimensional array of many different functional blocks, such as programmable logic blocks 32, embedded digital signal processing (DSP) blocks 34, embedded memory blocks 36, and embedded input-output blocks 38. In many cases, there may be rows or columns of these functional blocks that may be programmably connected to one another using programmable routing 40.

The programmable logic blocks 32 may be programmed to implement a wide variety of logic circuitry. The programmable logic blocks 32 may include a number of adaptive logic modules (ALMs), which may take the form of lookup tables (LUTs) that can be programmed to implement a logic truth table and flip-flops (FFs), effectively enabling any of the programmable logic blocks 32 to implement any desired logic circuitry when configured with the system design configuration 14. The programmable logic blocks 32 are sometimes referred to as logic array blocks (LABs) or configurable logic blocks (CLBs).

The embedded DSP blocks 34, embedded memory blocks 36, and embedded IO blocks 38 may be distributed around the programmable logic blocks 32. For example, there may be several columns of programmable logic blocks 32 for every column of DSP blocks 34, column of embedded memory blocks 36, or column of embedded IO blocks 38. The embedded DSP blocks 34 may include “hardened” circuits that are specialized to efficiently perform certain arithmetic operations. This is in contrast to “soft logic” circuits that may be programmed into the programmable logic blocks 32 to perform the same functions, but which may not be as efficient as the hardened circuits of the DSP blocks 34. The embedded memory blocks 36 may include dedicated local memory (e.g., blocks of 20kB, blocks of 1MB). The embedded IO blocks 38 may allow for inter-die or inter-package communication. The embedded DSP blocks 34, embedded memory blocks 36, and embedded IO blocks 38 may be accessible to the programmable logic blocks 32 using the programmable routing 40.

The various functional blocks of the programmable logic circuitry 30 may be grouped into programmable regions, sometimes referred to as logic sectors, that may be individually managed and configured by corresponding local controllers 42 (e.g., sometimes referred to as Local Sector Managers (LSMs)). The grouping of the programmable logic circuitry 30 resources on the integrated circuit device 12 into logic sectors, logic array blocks, logic elements, or adaptive logic modules is merely illustrative. In general, the integrated circuit device 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 30 of the integrated circuit device 12 may be controlled by programmable memory elements sometimes referred to as configuration random access memory (CRAM). Memory elements may be loaded with configuration data (also called programming data or a configuration bitstream) that represents the system design configuration 14. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables (LUTs), logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these.

A device controller 44, sometimes referred to as a secure device manager (SDM), may manage the operation of the integrated circuit device 12. The device controller 44 may include any suitable logic circuitry to control and/or program the programmable logic circuitry 30 or other elements of the integrated circuit device 12. For example, the device controller 44 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally, or alternatively, the device controller 44 may include a hardware finite state machine (FSM). The device controller 44 may provide other functions, such as serving as a platform for virtual machines that may manage the operation of the integrated circuit device 12.

A network-on-chip (NOC) 46 may connect the various elements of the integrated circuit device 12. The NOC 46 may provide rapid, packetized communication to and from the programmable logic circuitry 30 and other blocks, such as a hardened processor system 48, high-speed input-output (IO) blocks 50, a hardened accelerator 52, and local device memory 54. The integrated circuit device 12 may include the hardened processor system 48 when the integrated circuit device 12 takes the form of a system-on-chip (SOC). The hardened processor system 48 may include a hardened processor (e.g., an x86 processor or a reduced instruction set computer (RISC) processor, such as an Advanced RISC Machine (ARM) processor or a RISC-V processor) that may act as a host machine on the integrated circuit device 12. The high-speed IO blocks 50 may enable communication using any suitable communication protocol(s) with other devices outside of the integrated circuit device 12, such as a separate memory device. The hardened accelerator 52 may include any hardened application-specific integrated circuitry (ASIC) logic to perform a desired acceleration function. For example, the hardened accelerator 52 may include hardened circuitry to perform cryptographic or media encoding or decoding. The memory 54 may provide local device memory (e.g., cache) that may be readily accessible by the programmable logic circuitry 30.

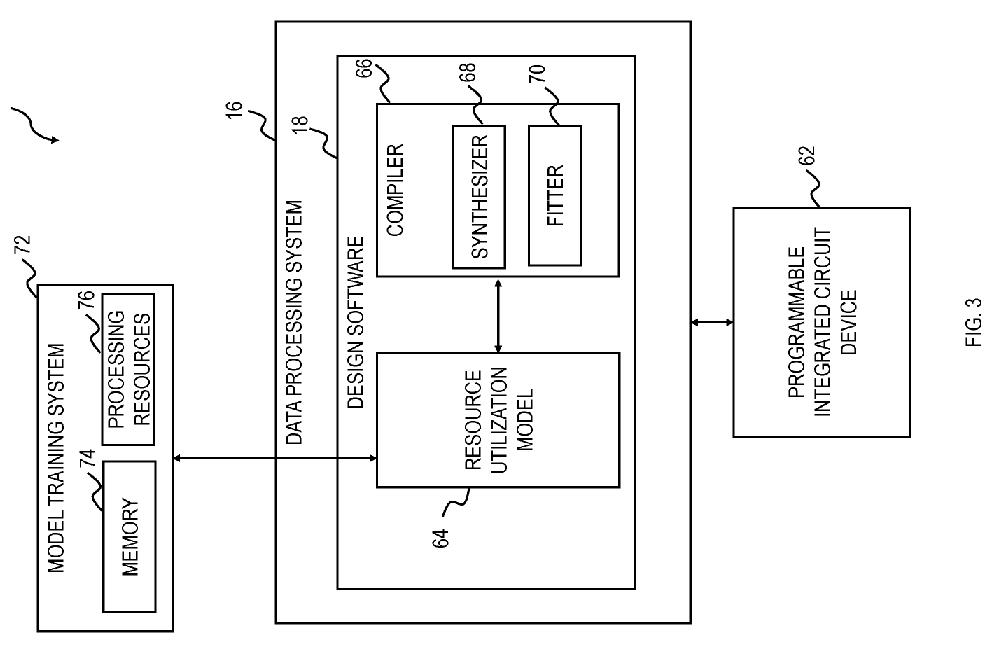

With this background in mind, FIG. 3 is a diagram 60 of a data processing system 16 with design software 18, including a resource utilization model 62, for programming a programmable integrated circuit device 64 (e.g., the integrated circuit device 12 of FIGS. 1 and 2). As described above, the data processing system 16 may be used to configure and/or reconfigure a programmable integrated circuit device 64. Thus, as depicted in this diagram, the data processing system 16 may include (e.g., host) or provide access to design software 18. As depicted, the design software 18 also may include the resource utilization model 62. The resource utilization model 62 may be any suitable model, such as an XGBoost model, a multilayer perceptron model (MLP), a support vector machines (SVM), a Linear Regression model, any other suitable machine learning model, or a combination of multiple machine learning models. In aspects of the present disclosure, the resource utilization model 62 may be a relatively lightweight model (e.g., less than 5 megabytes) that may be installed and accessed locally on a device running the design software 18 (e.g., the resource utilization model 62 may be a local application included in the design software). Additionally or alternatively, the resource utilization model 62 may be hosted on a separate computing device (e.g., a server or collection of servers) that may be accessed by the design software 18, such as over the Internet.

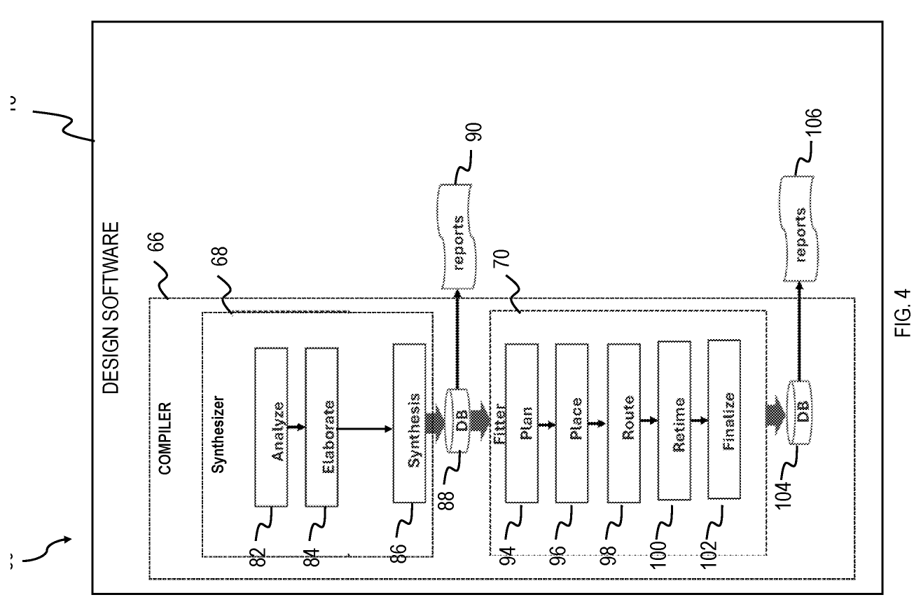

The design software 18 may include a compiler 66 for configuring the programmable integrated circuit device 64. The compiler 66 may include a synthesizer 68 and a fitter 70. As will be discussed with reference to FIG. 4, each of these systems may perform steps in a design implementation flow for configuring a programmable integrated circuit device 64 based on a system design. Although this disclosure describes the synthesizer 68 and the fitter 70 as separate systems within the compiler 66, in some design software implementations the synthesizer 68 and the fitter 70 may be viewed as a common system or collection of processes. In any case, the compiler 66 may receive a system design (e.g., a VHDL or Verilog file including RTL code). The synthesizer 68 may perform elaboration, optimization, and technology mapping on the received system design. For example, the synthesizer 68 may generate a circuit graph of primitives based on the system design. The synthesizer 68 also may generate a technology-mapped netlist based for the programmable integrated circuit device 64 based on the circuit graph. More specifically, the synthesizer 68 may map the primitive gates to programmable logic circuit elements, such as LUTs and/or flip-flops, which may be implemented on the programmable integrated circuit device 64. In some aspects, the synthesizer 68 also may predict programmable logic blocks (e.g., RAM blocks and/or DSP blocks) that may be implemented on the programmable integrated circuit device 64 based on the circuit graph. The fitter 70 may place and route the technology-mapped netlist onto the programmable integrated circuit device 64. For example, the fitter 70 may cluster programmable logic circuit elements (e.g., LUTs and flip-flops) in the technology-mapped netlist to ALMs, LABs, or other programmable integrated circuit device resources based on the legal constraints and technical specifications (e.g., vendor-specific and/or device-specific configurations) of the programmable integrated circuit device 62. The fitter 70 also may perform clock allocation and retiming for the programmable integrated circuit device 64. In some cases, the fitter 70 may generate a configuration file that may be applied to the programmable integrated circuit device 64 to implement the system design in the programmable fabric of the programmable integrated circuit device 64.

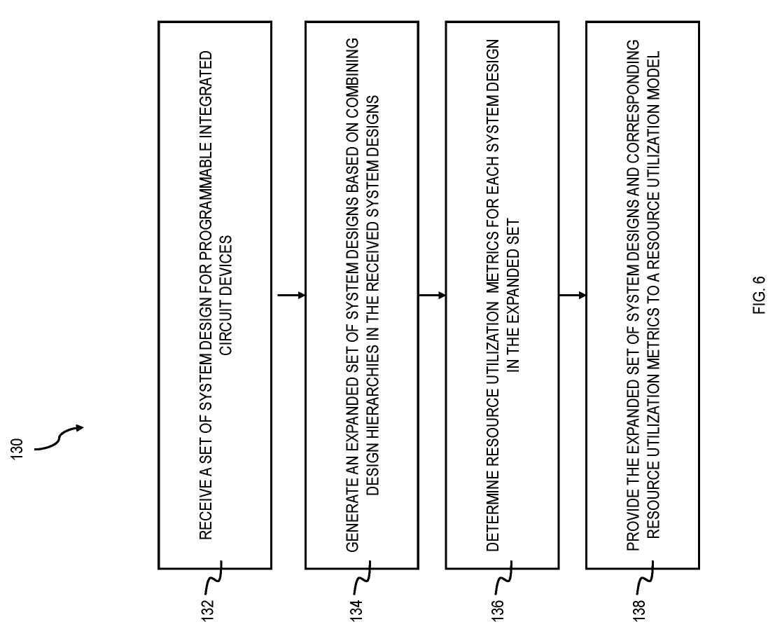

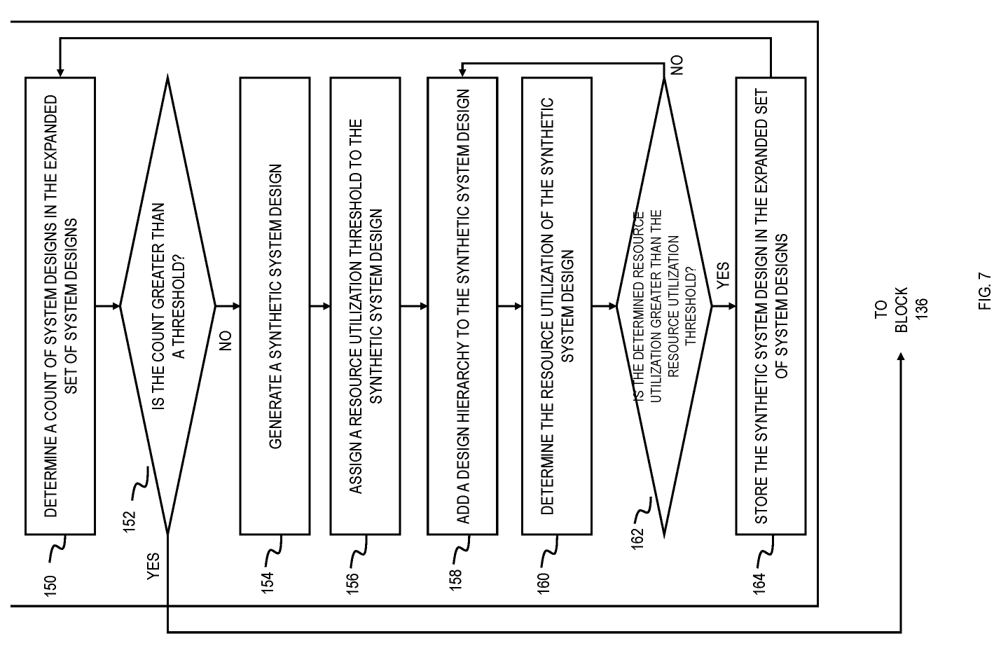

In some aspects, the data processing system 16 may be communicatively coupled to a model training system 72. More specifically, the resource utilization model 62 may be communicatively coupled to the model training system 72. The model training system 72 may be any suitable computing device or collection of computing devices, such as a desktop, a server, a collection of servers, or the like. As will be described with reference to FIGS. 6 and 7, the model training system 72 may generate training data and/or provide the training data to the resource utilization model 62. The resource utilization model 62 may use the training data received from the model training system 72 during an initial training phase and/or during subsequent refining or fine-tuning phases. The model training system 72 may include memory 74 and processing resources 76 (e.g., processing circuitry, one or more processors). The memory 74 may include non-transitory, computer-readable media that may store instructions, which may be executed by the processing resources 76 to perform operations described herein, including generating synthetic training data and/or providing the training data to the resource utilization model 62. Although depicted as a separate system in this example, in some respects, the model training system 72 may be included in the data processing system 16 and/or the design software 18.

Turning to a more detailed description of the design implementation flow, FIG. 4 is an example of a design implementation flow 80 for configuring a programmable integrated circuit device 64. According to aspects of this disclosure, the design implementation flow 80 includes an intermediate resource utilization report that may include one or more resource utilization metrics predicted by the resource utilization model 62. The design implementation flow 80 depicted in this example describes a number of discrete steps that may be performed by the compiler 66 during configuration of the programmable integrated circuit device 64. More specifically, the design implementation flow 80 may be broken down into a first stage synthesis steps performed by the synthesizer 68 and a second stage of fitter steps that may be performed by the fitter 70. The design implementation flow 80 may begin with design software 18 receiving RTL code (e.g., a VHDL or Verilog file) indicating a system design to be implemented in programmable fabric of the programmable integrated circuit device 64. After receiving the RTL code, the synthesizer 68 may generate a circuit graph of primitives based on the RTL code. In an analysis step 82, the synthesizer 68 may parse the RTL code for syntax and/or semantic errors. The synthesizer 68 also may create a design tree or another suitable representation of the system design. In an elaboration step 84, the synthesizer 68 may translate a behavior of RTL descriptions in the RTL code into the circuit graph of primitives. For example, in the case of an FPGA, the compiler 66 may convert statements in the RTL code into basic FPGA primitives, such as multiplexers, registers, and/or logic gates. The compiler 66 also may perform early optimizations, such as removing logic that does not drive an output and/or resolving definite parameters (e.g., set values).

After generating the circuit graph of primitives at the elaboration step 84, the design implementation flow 80 may include a synthesis step 86. In the synthesis step 86, the synthesizer 68 may generate a technology-mapped netlist based on the circuit graph of primitives. The technology-mapped netlist may be a technology dependent representation of the circuit graph of primitives (e.g., for a particular programmable integrated circuit device architecture). To generate the technology-mapped netlist, the synthesizer 68 may simplify logic in the circuit graph of primitives (e.g., using Boolean algebra to simplify complex logic). The synthesizer 68 also may determine shared hardware resources. In some respects, the synthesizer 68 may map the circuit graph to programmable logic circuit elements. For example, the synthesizer 68 may replace and/or group the basic primitives into programmable logic circuit elements (e.g., LUTs, flip-flops, DSP blocks, RAM blocks). Additionally, or alternatively, the synthesizer 68 may infer carry chain elements and/or adder chains. After the synthesis step 86 and before the technology-mapped netlist is fit to the programmable integrated circuit device 64, the technology-mapped netlist may be stored in a data structure 88 (e.g., a database, a repository). For example, the technology-mapped netlist may be stored in the data structure to limit re-synthesis time if certain aspects or portions of the technology-mapped netlist are changed (e.g., due to designer changes to the system design). Additionally, the data structure 88 may store the technology-mapped netlist for implementation on multiple programmable integrated circuit devices (e.g., different programmable integrated circuit devices). According to aspects of the present disclosure, after generating the technology-mapped netlist at the synthesis step 86, the design implementation flow 80 may provide a predicted resource utilization report 90. The design software 18 may generate the predicted resource utilization report 90 based on resource utilization metrics that are predicted by the resource utilization model 62, which may be trained to determine the resource utilization metrics based on the technology-mapped netlist. The predicted resource utilization report 90 may include an indication as to ALMs that may be used by the system design, LABs that may be used by the system design, more granular programmable logic circuit elements (e.g., LUTs, flip-flops) that may be used by the system design, and additional features that may be included in the system design. As will be discussed in more detail below, the resource utilization model 62 may provide an advantage in terms of an early prediction of resource utilization before fitting technology-mapped netlist onto the programmable integrated circuit device 64. For example, a designer may adjust the system design and/or the technology-mapped netlist early in the design implementation flow 80. In some cases, the designer may iteratively update a system design based on the predicted resource utilization report 90. For example, the designer may change their system design (e.g., to affect resource usage and/or resource mix associated with their system design) or their programmable integrated circuit device selection. It may be desirable for a designer to have this flexibility after the synthesis step 86 in the design implementation flow 80 to enable designers to improve efficiency metrics, such as reducing their costs per programmable device resources used. It should be noted that although the current design implementation flow 80 depicts the predicted resource utilization report 90 after the synthesis step 86, in some respects, the resource utilization model 62 may predict the resource utilization metrics based on the circuit graph of basic primitives at the elaboration step 84. That is, the resource utilization model 62 may be configured to generate predicted resource utilization metrics at early stages in the design implementation flow 80 throughout the steps performed by the synthesizer 68.

After generating the technology-mapped netlist, the design implementation flow 80 may include a number of fitting steps. For example, in a plan step 92, the fitter 70 may locate dedicated hardware blocks in the programmable integrated circuit device 64. For example, the fitter 70 may locate I/O pins, phase-locked loop (PLL) blocks, memory blocks, and the like. The fitter 70 also may perform clock allocation. At a place step 96, the fitter 70 may assign programmable logic circuit elements (e.g., LUTs and/or flip-flops) to adaptive logic modules (ALMS) and/or Logic Array Blocks (LABs). The fitter 70 also may apply various optimization techniques to limit (e.g., reduce, minimize) wire length and/or congestion during placement of the programmable logic circuit elements. In a route step 98, the fitter 70 may connect the placed programmable logic circuit elements within the programmable integrated circuit device 64 using interconnect resources. In some aspects, the fitter 70 may map connections between programmable logic circuit elements over the routing fabric based on timing constraints and specifications. For example, during the place step 96 and/or route step 98 the fitter may optimize wiring usage, setup timing and hold timing, apply algorithms to reduce routing congestions, and confirm that the placed logic circuit elements comply with legal constraints (e.g., vendor and/or device specifications) and practical constraints (e.g., that physical resources on programmable integrated circuit device 64 are not overutilized). Additionally, during these steps, the fitter 70 may use placement information to cluster programmable logic circuit elements (e.g., LUTs and/or flip-flops) into ALMs and/or LABs based on the legal constraints of the FPGA and/or optimize the clustering of the programmable logic circuit elements based on their respective functions. At a retiming step 100, the fitter may perform sequential optimizations by moving programmable logic elements and/or logic cells (e.g., registers) across the combinational logic to limit path delays and/or improve potential operating frequency. At a finalize step 102, the fitter may finalize timing by adding delays to fix any hold violations. In some aspects, the fitter 70 may output a configuration file at the finalize step 102. The configuration file may include a bitstream that may be applied (e.g., pushed) to the programmable integrated circuit device 64 to configure or reconfigure the programmable integrated circuit device 64.

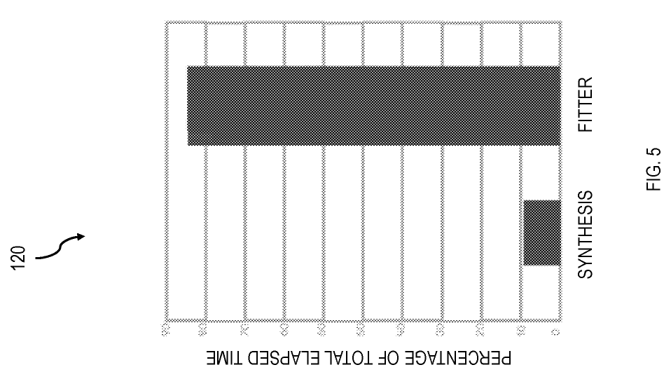

After the finalize step 102, the configuration file may be stored in a data structure 104 (e.g., a database, a repository). The data structure 104 may be the same as the data structure 88 described above or it may be a separate data structure. In some cases, the design implementation flow 80 may provide a post-fit resource utilization report 106 at this stage. For example, without aspects of the present disclosure, some systems may use heuristics to generate the post-fit resource utilization report 106 based on resource allocations and definitions included in the configuration file. However, as described above, one benefit of the preset disclosure includes generating the predicted resource utilization report 90 earlier in the design implementation flow 80. Indeed, the resource utilization model 62 may use artificial intelligence systems and methods to generate the predicted resource utilization report 90 after the elaborate step 84 and/or the synthesis step 86. To help demonstrate this benefit, FIG. 5 is a graph depicting time elapsed during the synthesis steps compared to the time elapsed in the fitter steps in the design implementation flow 80. Depending on the system design, the synthesizer 68 operations (steps 82-86 in the design implementation flow 80) may demand significantly less time than the fitter 70 operations (steps 94-102 in the design implementation flow 80). For example, in some cases, the synthesizer steps may account for less than 10% of elapsed time in the design implementation flow 80. Conversely, the fitter steps may account for more than 80% of the elapsed time in the design implementation flow 80. Accordingly, generating the predicted resource utilization report 90 at the end of the synthesis step 86 may enable designers to modify their system design before the time and resource intensive steps performed by the fitter. Further the predicted resource utilization report 90 may provide a benefit to designers as it may enable them to perform early design exploration. For example, designers may use the predicted resource utilization report 90 to modify their system design and/or perform device selection that best matches their application’s needs. In some cases, designers may use the predicted resource utilization report to optimize efficiency or cost metrics, such as reducing costs per programmable integrated circuit device resources. As noted above, the resource utilization model 62 may generate the predicted resource utilization report 90 in negligible time relative to the synthesis and fitting steps in the design implementation flow 80.

Turning now to a more detailed look at the resource utilization model 62, FIG. 6 is a flowchart illustrating a method 130 of training the resource utilization model 62. Although the following description of the method 130 is described as being performed by the model training system 72, any suitable computing device (e.g., any device having a processor and memory), including the resource utilization model 62 itself, may perform the steps described herein. Although the method 130 is described in a particular order, it should be understood that the method 130 may be performed in any suitable order and may exclude one or more of the blocks described herein.

At block 132, the model training system 72 may receive a set of system designs for multiple programmable integrated circuit devices. The set of system designs may refer to actual system designs that have been previously implemented using design software 18 (e.g., client system designs). In some aspects, the set of system designs may be defined in a library that may be associated with a manufacturer library (also referred to as a vendor library) or developer of programmable integrated circuit devices. In any case, at block 132, the set of system designs may refer to system designs that have been previously implemented and/or validated. Accordingly, the set of system designs may be viewed as actual training data. However, as may be appreciated, access to system designs may be limited and there is an indeterminable number of possible system designs that could be implemented on a programmable logic device. Thus, synthetic training data (e.g., synthetic or artificial system designs) may be useful for training, refining, and fine-tuning the resource utilization model 62. As used herein, “synthetic system designs” may refer to compilations of RTL code (e.g., design hierarchies) that may be combined and provided to the resource utilization model as training data. Accordingly, the synthetic system designs may not be intended or structured to perform a particular task on a programmable integrated circuit device. However, the synthetic system designs may be useful as training data for providing a wide variety of design hierarchies to the resource utilization model 62 for training.

Accordingly, at block 134, the model training system 72 may generate an expanded set of system designs based on combining different design hierarchies in the received set of system designs. In some aspects, the model training system 72 may identify design hierarchies in the system designs. Design hierarchies may refer to the modular portions of the RTL code that specifies a system design. More specifically, design hierarchies may refer to modules and sub-modules (e.g., including multi-level sub-modules defined in a tree-like manner) that may be arranged in a hierarchical relationship. As will be discussed in more detail with reference to FIG. 7, the resource utilization model 62 may extract and combine design hierarchies from the set of system designs (e.g., the actual training data) to generate the synthetic training data.

At block 136, the model training system 72 may determine resource usage metrics for each system design in the expanded set of system designs. In some aspects, the model training system 72 may implement the expanded set system designs to determine resource usage metrics based on a resource utilization report (e.g., the post-fit resource utilization report 106 in FIG. 4). For example, the model training system 72 may implement each system design in the expanded set of system designs via the design software 18 and the design implementation flow 80 described with reference to FIG. 4. In some aspects, the model training system 72 may implement a portion of the expanded set of system designs. For example, the model training system 72 may implement the portion of the expanded set of system designs that includes the actual system designs (e.g., the actual system designs in the manufacture library at block 132) via the design software 18 and the design implementation flow 80 described with reference to FIG. 4. In these cases, the model training system 72 may determine the resource usage metrics associated for the synthetic system designs based on preexisting resource utilization metrics associated with the design hierarchies of the actual system designs. For example, if a synthetic system design includes two design hierarchies, the model training system 72 may determine its resource utilization metrics based on the sum of resources used by both design hierarchies. The expanded set of system designs and the corresponding resource usage metrics may be used to train the resource utilization model 62 to predict resource utilization metrics based on the technology-mapped netlist. For example, a portion of the expanded set of the system designs (e.g., the synthetic training data) may be used by the resource utilization model 62 as training data, and a second portion of the expanded set of system designs (e.g., the actual training data) may be used by the resource utilization model 62 as testing and/or validation data. In some aspects, the resource utilization model 62 may generate additional training data at this stage. For example, the resource utilization model 62 may compile the expanded set of system designs using different routing seeds (e.g., initial routing locations for programmable logic circuit elements). In at least these ways, the model training system 72 may generate a significant amount of training data to increase the accuracy of the resource utilization predictions provided by the resource utilization model 62.

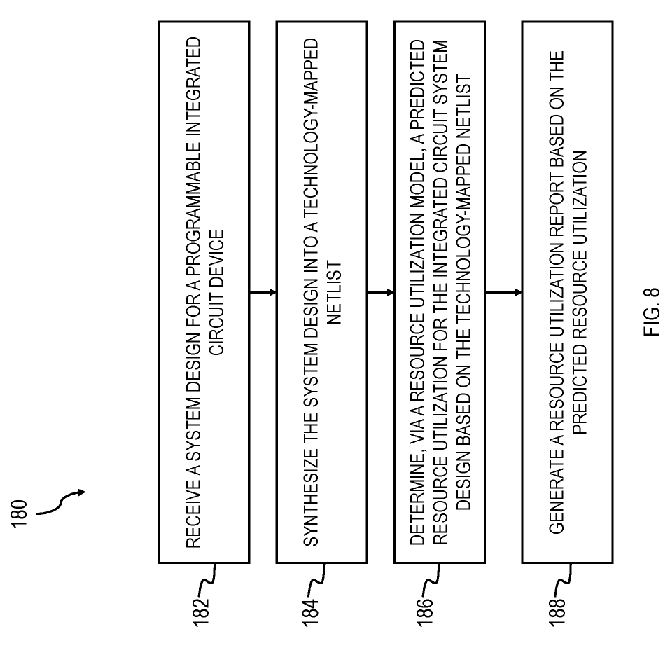

At block 138, the model training system 72 may provide the expanded set of system designs and corresponding resource usage reports to the resource utilization model 62 for model training. The resource utilization model 62 may be any suitable machine learning model, including supervised or unsupervised machine learning models. To provide an example, in cases where the resource utilization model 62 is an XGBoost model, the resource utilization model 62 may train multiple decision trees based on a training algorithm, such as gradient boosting with least-squares loss. The resource utilization model 62 may sequentially add and train decision trees to limit (e.g., reduce) any residual prediction errors. In some aspects, the resource utilization model 62 may be trained based on a number of hyperparameters, including a maximum tree depth, a number of trees, and/or a learning rate. Moreover, the resource utilization model 62 may be tuned based on regularization parameters (e.g., L1/L2 regularization) by applying a grid search on a validation set (e.g., the actual training data). The resource utilization model 62 may output a number of inferences, including scalar estimates of resource utilization metrics, which may be included in the predicted resource utilization report 90. After training, the resource utilization model 62 may be implemented in the design software 18. The resource utilization model 62 may receive a system design (e.g., from a designer) and may predict resource usage after the synthesis step 86 in the design implementation flow 80. More specifically, as will be described with reference to FIG. 8, the resource utilization model 62 may receive the technology-mapped netlist from the synthesis model, identify the relevant features based on the technology-mapped netlist, and generate the resource utilization report.

In some aspects, the resource utilization model 62 may be trained based on feature engineering. For example, the resource utilization model 62 may be trained on “K” features with the highest correlation to resource usage (e.g., based on comparing mutual information scores between resource utilization metrics and various features), where “K” may be any positive integer. Turning to a few non-exhaustive examples of the features that the resource utilization model may receive and/or identify based on the technology-mapped netlist, the resource utilization model 62 may identify aggregate counts of programmable logic elements (e.g., LUTs, flip-flops) at the end of synthesis. In some cases, the resource utilization model 62 may granularly identify counts of LUTs based on the number of inputs the LUTs are configured to receive. For example, the resource utilization model 62 may identify counts of “M” input LUTs, where “M” may be any positive integer (e.g., typically between 1 and 8). Additionally or alternatively, the resource utilization model 62 may be trained to identify structural patterns, such as LUT-to flip-flop single-fan-out pairs (e.g., register-packing candidates) and flip-flop-to-LUT pairs (e.g., Hyperflex register candidates). In aspects of the present disclosure, the resource utilization model 62 may be trained to identify other programmable logic circuit elements, including RAM blocks and corresponding bit allocations, DSP blocks and their corresponding bit allocations, I/O pins, and/or interconnect resources (e.g., carry-chain elements). In some aspects, the resource utilization model may identify connectivity features associated with the programmable integrated circuit device 64. For example, the resource utilization model 62 may be trained to count “N” to “O” fan-out structures, where “N” and “O” are both positive integers (e.g., typically between 1 and 64). As described above, the resource utilization model 62 may receive categorical features (e.g., qualitative values) associated with a type of programmable integrated circuit device (e.g., a manufacture, a device family) and/or enabled settings on the programmable integrated circuit device. For example, the resource utilization model 62 may receive one or more indications as to enabled optimization settings, including whether the device is balanced, high-effort, area-optimized, and/or the like. The resource utilization model 62 may use any of these features in predicting the resource utilization metrics that may be included in the predicted resource utilization report 90. It should also be noted that the design software 18 may include any of these features in the predicted resource utilization report 90.

With this in mind, the resource utilization model 62 may demand a significant amount of training data to accurately identify the preceding features in a wide variety of system designs and corresponding technology-mapped netlists. As mentioned with reference to blocks 136, the model training system 72 may generate an expanded set of system designs based on combining design hierarchies from the received system designs (e.g., the actual training data). Looking into this step in more detail, FIG. 7 is a flowchart illustrating steps that the model training system 72 may use for generating the expanded set of system designs described with reference to FIG. 6. Although the following steps may be performed by the model training system 72, any suitable computing device (e.g., any device having a processor and memory), including the resource utilization model 62 itself, may perform the steps described herein. Additionally, although the following steps are described as blocks arranged in a particular order, it should be understood that these steps may be performed in any suitable order and may exclude one or more of the blocks described herein.

At block 150, the model training system 72 may determine a count of system design samples in the expanded set of system designs. In the first instance, the count of system designs may refer to the set of actual system designs received by the model training system 72 (block 132 in FIG. 6). However, as will be discussed in more detail below, the count may be incremented as synthetic system designs are added to the expanded set of system designs increases.

At decision block 152, the model training system 72 may determine whether the count of system design samples in the expanded set of system designs is greater than or equal to a threshold number of training samples. The threshold number of training samples may be any suitable number (e.g., 500 system designs, 275,000 system designs, over 1,000,000 system designs). If the count of system design is greater than or equal to the threshold number of training samples, the model training system 72 may continue to block 136 in the method 130 of FIG. 6. However, if the count of system designs is less than the threshold number of training samples, then, at block 154, the model training system 72 may generate a synthetic system design. Initially, the synthetic system design may be empty. However, design hierarchies from a portion of the expanded set of system designs (e.g., the actual training data) may be added to the synthetic system design based on the iterative process described in blocks 158-162.

At block 156, the model training system 72 may determine a resource utilization threshold for the synthetic system design. In some cases, it may be desirable to train the resource utilization model 62 on a diverse set of training data that includes synthetic designs with various resource utilizations. To provide an example, the resource utilization threshold may refer to a pseudo-randomly assigned percentage of resource utilization that may range from 10% resource utilization to 100% resource utilization. More specifically, the model training system 72 may use a random or pseudo-random selection algorithm to determine a resource utilization threshold to apply to the synthetic system design. However, in certain cases, the resource utilization range may be changed (e.g., 15% resource utilization to 95% resource utilization, 5% resource utilization to 98% resource utilization). In any case, each synthetic system design may be assigned a resource utilization threshold.

At block 158, the model training system 72 may add a design hierarchy to the synthetic system design. In some aspects, the model training system may retrieve a random or pseudo-random hierarchy from the received system designs (block 132 of FIG. 6) based on a selection algorithm and add the random design hierarchy to the synthetic system design. It should be noted that the selection of the random or pseudo-random design hierarchy may be acceptable for the synthetic system designs because they are used to train the resource utilization model 62. Thus, in some cases, placing and routing the random design hierarchies (e.g., the fitting steps) may have a limited impact on training the resource utilization model 62 for predicting resource utilization metrics. In other aspects, the model training system 72 may selectively retrieve a design hierarchy from the received system designs (block 132 of FIG. 6) based on one or more design characteristics. In some cases it may be desirable to train the resource utilization model 62 on a specific design characteristics to increase the ability of the resource utilization model 62 to respond to certain combinations of resources. For example, in some cases, the model training system 72 may select design hierarchies that have a threshold number of 5 input LUTs, a threshold number of RAM blocks, a threshold number of DSP blocks, or any other deterministic resource value. In some aspects, the model training system 72 may use artificial intelligence systems or methods to select design hierarchies that may have diverse resource characteristics to train the resource utilization model 62 on a wide range of synthetic designs.

At block 160, the model training system 72 may determine a resource utilization for the synthetic system design. For example, the model training system 72 may calculate the resource utilization associated with the synthetic system design based on the design hierarchy that is added to the synthetic system design. For example, in some aspects, each random design hierarchy may be associated with predetermined resource utilization metrics based on previous implementations and/or post-fit resource utilization reports 106. More specifically, the model training system 72 may generate a resource utilization report for each of the received system designs (e.g., the actual training data). In some aspects, the resource utilization report may include a granular design-hierarchy-level resource usage indication. The model training system 72 may sum the resource usage indications for each design hierarchy to determine a total resource utilization of the synthetic system design. In at least this way, the model training system 72 may efficiently calculate the resource utilization for the synthetic system design without having to recompile the synthetic system design each time a design hierarchy is added. However, in additional or alternative aspects, the model training system 72 may determine resource utilization based on compiling and fitting the synthetic system design according to design implementation flow 80 described with reference to FIG. 4 (e.g., based on the post-fit resource utilization reports 106).

At decision block 162, the model training system 72 may determine whether the determined resource utilization (block 160) is greater than or equal to the assigned resource utilization threshold (block 156). If the determined resource utilization is less than the assigned resource utilization threshold, then the model training system 72 may return to block 158 and continue incrementally adding random design hierarchies to the synthetic system design until the calculated resource utilization is greater than or equal to the assigned resource utilization threshold. Conversely, if the calculated resource utilization is greater than or equal to assigned resource utilization threshold, then, at block 164, the model training system 72 may add the synthetic system design to the expanded set of system designs. After this stage, the model training system 72 may return to block 150 to determine (e.g., increment) the count of the system designs in the expanded set of system designs. As mentioned above, this process may be repeated until the count of system designs in the expanded set of system designs is greater than or equal to a threshold number of training samples (decision block 152). Once the expanded set of system designs is greater than or equal to the threshold number of training samples, the model training system 72 may proceed to block 136 in the method 130 to compile the expanded set of system designs and determine corresponding resource utilization metrics. In at least these ways, aspects of the present disclosure include systems and methods for generating synthetic or artificial training data that may improve the ability of the resource utilization model 62 to inference resource utilization metrics across a wide range of system designs.

Turning to an example use case for the resource utilization model 62 after the training phase, FIG. 8 is a flowchart illustrating a method 180 for design software 18 to generate a predicted resource utilization report after a synthesis step in the design implementation flow 80 of FIG. 4. Although the following description of the method 180 is described as being performed by the design software 18 that includes a resource utilization model 62, other types of design software that may include or may access other suitable models also may perform this method 180. Additionally, although the method 180 is described in a particular order, it should be understood that the method 180 may be performed in any suitable order and may exclude one or more of the blocks described herein.

At block 182, the design software 18 may receive a system design for a programmable integrated circuit device 64. The system design may be drafted or provided from a designer and may include one or more desired behaviors to be implemented on a programmable integrated circuit device 64. At block 184, the design software 18 may synthesize the system design into a technology-mapped netlist. More specifically, the design software 18 may generate the technology-mapped netlist based on the design implementation flow 80 described with reference to FIG. 4.

At block 186, the design software 18 may determine, via a resource utilization model 62, a predicted resource utilization for the integrated circuit system design based on the technology-mapped netlist. As mentioned, the resource utilization model 62 may run locally within the design software 18. The resource utilization model 62 may be trained to determine (e.g., predict) one or more resource utilization metrics based on the technology-mapped netlist. For example, the resource utilization model 62 may be trained to determine a percentage of available programmable integrated circuit device resources that are expected to be used by the system design (e.g., based on a total number of ALMs and/or LABs). Additionally or alternatively, the resource utilization model 62 may be configured (e.g., based on a designer selection of potential resource utilization metrics) to determine more fine-grain resource utilization metrics, such as expected counts of programmable logic circuit elements. As mentioned above, because the resource utilization model 62 may be a pre-trained model (e.g., based on the method 130 described with reference to FIG. 6), the resource utilization model 62 may generate the predicted resource utilization metrics in negligible inference time (e.g., a time period that is insignificant relative to the other steps in the design implementation flow 80).

At block 188, the design software 18 may generate a predicted resource utilization report 90 based on the predicted resource utilization. The predicted resource utilization report 90 may include the predicted resource utilization metrics generated by the resource utilization model 62. The predicted resource utilization report 90 may be presented to and/or accessed by the designer. The designer may use the predicted resource utilization report 90 to identify possible changes to the system design and/or changes to the system architecture, including adding additional logic to the system design and/or implementing the system design on a different type of programmable integrated circuit device 64. In these ways, this method 180 may be performed iteratively by a designer in response to changes or updates to the system design. The designer may repeatedly use the resource utilization model 62 to evaluate updated system designs before the time-intensive fitting steps. Accordingly, the designer may be able to develop system designs without using potentially intensive timing and computing resources associated with fitting the system design onto the programmable integrated circuit device 64.

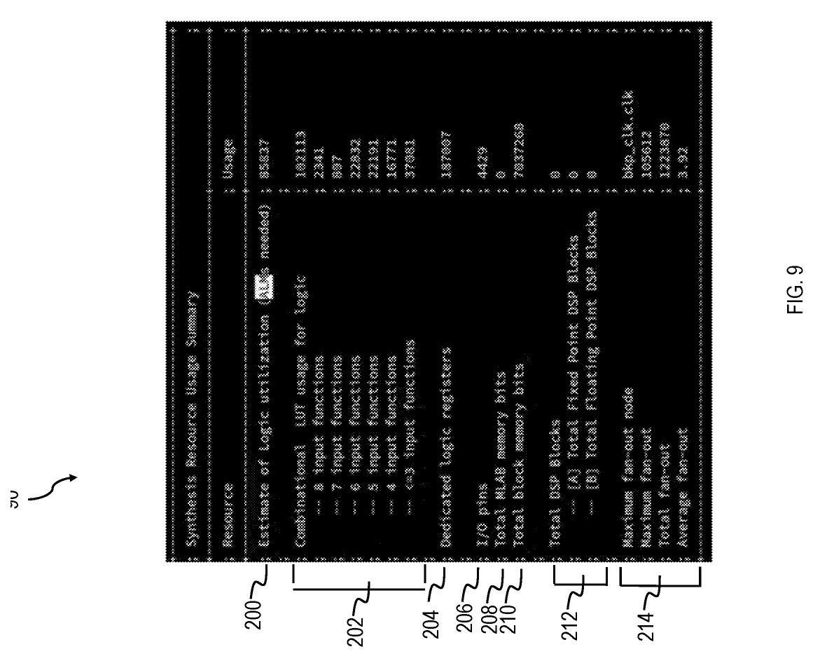

With this in mind, FIG. 9 is an example of a predicted resource utilization report 90 that may be generated based on the method 180 described with reference to FIG. 8. In this example, the resource utilization report includes a total logic estimate 200. In this case, the total logic estimate 200 includes a number of ALMs needed to implement the system design. However, in other cases, the total logic estimate 200 may refer to other suitable parameters for determining logic that may be occupied by the system design (e.g., a percentage or ratio of ALMs to implement the system design compared to available resources). The predicted resource utilization report 90 also includes an indication of LUTs 202, including an aggregate count of LUTs and a fine grain count of LUTs corresponding to a number of inputs. The predicted resource utilization report 90 may include a count of dedicated logic registers 204, I/O pins 206, memory logic array bock (MLAB) bits 208, and block memory bits 210 occupied by the system design. In this example, the predicted resource utilization report 90 further includes an indication of DSP blocks 212, including an aggregate count of DSP blocks, a number of fixer point DSP blocks and a number of floating point DSP blocks. Lastly, the predicted resource utilization report 90 includes structural patterns 214, such as a maximum fan-out node, a maximum fan-out (e.g., the maximum number of output signals fed by the output equations of a logic cell), a total fan-out, and an average fan-out (e.g., on a per logic cell basis). It should be noted that the resource utilization model may predict some of these values and/or identify some of these values (e.g., based on the technology-mapped list). For example, in some aspects, the resource utilization model 62 may be configured to predict the total logic estimate 200. The resource utilization model 62 may identify the other depicted values and use them as inputs for generating the total logic estimate 200.

As will be appreciated, the present systems and methods may provide significant value. The resource utilization model 62 disclosed herein may predict resource utilization metrics at a high level of accuracy due to training on the expanded set of system designs. For example, in comparative testing, the resource utilization model 62 may generate a predicted ALM count in the predicted resource utilization report 90 that is at least 95% accurate relative to the actual ALM count found in the post-fit resource utilization report 106. Moreover, the resource utilization model 62 may be relatively small and may run locally within design software 18. As a result, the resource utilization model 62 may demand limited computational resources to predict the resource utilization metrics that may be included in the predicted resource utilization report 90. Further, the resource utilization model 62 may generate the predicted resource utilization metrics in a time efficient manner (e.g., based on a negligible inference time) and at an early stage in the design implementation flow 80. In at least these ways, the resource utilization model 62 may improve a designer’s ability to efficiently evaluate system designs and make configuration decisions.

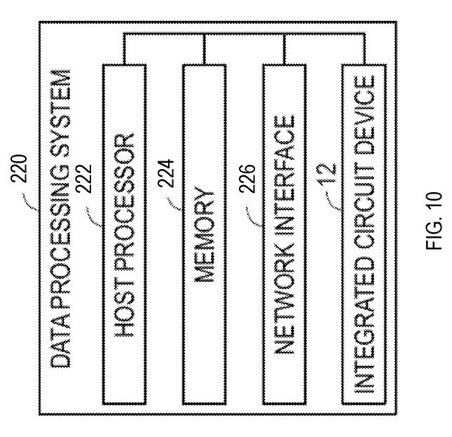

With the preceding in mind, the integrated circuit device 12 discussed above may be a component included in a data processing system, such as a data processing system 220, shown in FIG. 10. The data processing system 220 may include the integrated circuit device 12 (e.g., a programmable logic device, an application specific integrated circuit (ASIC)), a host processor 222, memory and/or storage circuitry 224, and a network interface 226. The data processing system 220 may include more or fewer components (e.g., electronic display, user interface structures, application specific integrated circuits (ASICs)). Moreover, any of the circuit components depicted in FIGS. 4, 6, and 8 may include the NOC 46 of the integrated circuit device 12. The host processor 222 may include any of the foregoing processors that may manage a data processing request for the data processing system 220 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 224 may include random access memory (RAM), read-only memory (ROM), one or more hard drives, flash memory, or the like. The memory and/or storage circuitry 224 may hold data to be processed by the data processing system 220. In some cases, the memory and/or storage circuitry 224 may also store configuration programs (e.g., bitstreams) for programming the integrated circuit device 12. The network interface 226 may allow the data processing system 220 to communicate with other electronic devices. The data processing system 220 may include several different packages or may be contained within a single package on a single package substrate. For example, components of the data processing system 220 may be located on several different packages at one location (e.g., a data center) or multiple locations. For instance, components of the data processing system 220 may be located in separate geographic locations or areas, such as cities, states, or countries.

The data processing system 220 may be part of a data center that processes a variety of different requests. For instance, the data processing system 220 may receive a data processing request via the network interface 226 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. A system comprising: a programmable integrated circuit device; and a data processing system configured to execute instructions stored on a tangible, non-transitory, computer-readable medium to: receive a system design for the programmable integrated circuit device; generate a technology-mapped netlist based on synthesizing the system design; determine, via a resource utilization model, a predicted resource utilization for the system design based on the technology-mapped netlist; and generate a resource utilization report based on the predicted resource utilization.

EXAMPLE EMBODIMENT 2. The system of example embodiment 1, comprising a model training system, wherein the model training system comprises: processing resources; and an additional tangible, non-transitory, computer-readable medium storing instructions that, when executed by the processing resources, cause the processing resources to generate synthetic training data to provide to the resource utilization model.

EXAMPLE EMBODIMENT 3. The system of example embodiment 2, wherein the instructions stored on the additional tangible, non-transitory, computer-readable medium cause the processing resources of the model training system to: receive a set of system designs for a plurality of programmable integrated circuit devices; generate an expanded set of system designs based on combining design hierarchies in the set of system designs to generate synthetic system designs; determine resource utilization metrics for each system design in the expanded set of system designs; and provide the expanded set of system designs and corresponding resource utilization metrics to the resource utilization model to be used by the resource utilization model as training data during a training phase.

EXAMPLE EMBODIMENT 4. The system of example embodiment 1, wherein the data processing system is configured to execute the instructions to: receive an indication comprising one or more changes to the system design, an alternative programmable integrated circuit device for implementing the system design, a resource mix to be used to implement the system design on the programmable integrated circuit device, or any combination thereof; and determine, via the resource utilization model, an additional predicted resource utilization based on the indication.

EXAMPLE EMBODIMENT 5. The system of example embodiment 1, wherein the predicted resource utilization comprises an indication of an amount of programmable logic on the programmable integrated circuit device that is expected to be occupied by the system design.

EXAMPLE EMBODIMENT 6. The system of example embodiment 1, wherein the resource utilization model is configured to determine the predicted resource utilization before fitting the technology-mapped netlist onto the programmable integrated circuit device.

EXAMPLE EMBODIMENT 7. The system of example embodiment 1, wherein the resource utilization model is trained to determine resource utilization for multiple programmable integrated device circuit device types, including field programmable gate arrays (FPGAs) and application-specific integrated circuits (ASICs).

EXAMPLE EMBODIMENT 8. A non-transitory, computer-readable medium, comprising computer-readable instructions that, when executed by a data processing system, cause the data processing system to: receive a system design for a programmable integrated circuit device; generate a technology-mapped netlist for the system design; and determine, via a resource utilization model, a predicted resource utilization for the system design based on the technology-mapped netlist, wherein the resource utilization model is configured to determine the predicted resource utilization before fitting the technology-mapped netlist onto the programmable integrated circuit device.

EXAMPLE EMBODIMENT 9. The non-transitory, computer-readable medium of example embodiment 8, wherein the instructions cause the data processing system to generate a predicted resource utilization report comprising one or more resource utilization metrics based on the predicted resource utilization, and wherein the one or more resource utilization metrics comprise a predicted amount of programmable logic on the programmable integrated circuit device, a predicted count of a programmable logic circuit element on the programmable integrated circuit device, or any combination thereof.

EXAMPLE EMBODIMENT 10. The non-transitory, computer-readable medium of example embodiment 8, wherein the instructions cause the data processing system to: receive a set of system designs from a manufacturer library, wherein the set of system designs corresponds to actual training data; generate an expanded set of system designs based on combining design hierarchies in the set of system designs, wherein the expanded set of system designs comprises synthetic training data and the actual training data; determine resource utilization metrics for each system design in the expanded set of system designs; and provide the expanded set of system designs and corresponding resource utilization metrics to the resource utilization model to be used by the resource utilization model during training.

EXAMPLE EMBODIMENT 11. The non-transitory, computer-readable medium of example embodiment 10, wherein the resource utilization model is trained based on feature engineering to identify one or more features in the technology-mapped netlist based on a correlation between the one or more features and the resource utilization metrics for each system design in the expanded set of system designs.

EXAMPLE EMBODIMENT 12. The non-transitory, computer-readable medium of example embodiment 8, wherein the instructions cause the data processing system to: store the technology-mapped netlist in a data repository before fitting the technology-mapped netlist onto the programmable integrated circuit device; and generate a predicted resource utilization report based on the predicted resource utilization for the system design before fitting the technology-mapped netlist onto the programmable integrated circuit device.

EXAMPLE EMBODIMENT 13. The non-transitory, computer-readable medium of example embodiment 12, wherein the instructions cause the data processing system to: generate a post-fit resource utilization report after fitting the technology-mapped netlist onto the programmable integrated circuit device, wherein the predicted resource utilization report and the post-fit resource utilization report include at least one common resource utilization metric, and wherein the at least one common resource utilization metric in the predicted resource utilization report is at least 95% accurate relative to the post-fit resource utilization report.

EXAMPLE EMBODIMENT 14. The non-transitory, computer-readable medium of example embodiment 8, wherein fitting the technology-mapped netlist onto the programmable integrated circuit device corresponds to a greater timing cost than generating the technology-mapped netlist based on synthesizing the system design.

EXAMPLE EMBODIMENT 15. A method of training a machine learning model for predicting resource utilization metrics in a programmable integrated circuit device comprising: receiving a set of training data comprising a plurality of actual system designs from a library; generating an expanded set of training data comprising the plurality of actual system designs and a plurality of synthetic system designs based on operations comprising iteratively: based on the count of system designs in the expanded set of training data being less than or equal to a count threshold: generating a synthetic system design; assigning a resource utilization threshold to the synthetic system design; in response to a determined resource utilization of the synthetic system design being less than the resource utilization threshold, iteratively adding design hierarchies to the synthetic system design until the determined resource utilization of the synthetic system design is greater than or equal to the resource utilization threshold; and in response to the determined resource utilization of the synthetic system design being greater than or equal to the resource utilization threshold, adding the synthetic system design to the expanded set of training data; and training the machine learning model to predict the resource utilization metrics for the programmable integrated circuit device based on the expanded set of training data.

EXAMPLE EMBODIMENT 16. The method of example embodiment 15, comprising training the machine learning model based on the synthetic system designs in the expanded set of training data and validating the machine learning model on the plurality of actual system designs in the expanded set of training data.

EXAMPLE EMBODIMENT 17. The method of example embodiment 15, wherein each actual system design in the set of training data comprises a plurality of design hierarchies, and wherein iteratively adding the design hierarchies to the synthetic system design comprises selecting a design hierarchy from the plurality of design hierarchies based on one or more resource utilization characteristics of the design hierarchy or selecting the design hierarchy from the plurality of design hierarchies based on a pseudo-random selection algorithm.

EXAMPLE EMBODIMENT 18. The method of example embodiment 15, wherein each actual system design in the set of training data comprises a plurality of design hierarchies, wherein each design hierarchy in the plurality of design hierarchies is associated with a predetermined resource utilization metric, and wherein generating the expanded set of training data based on the iterative operations comprises determining the resource utilization of the synthetic system design based on summing the predetermined resource utilization metrics for each design hierarchy added to the synthetic system design.

EXAMPLE EMBODIMENT 19. The method of example embodiment 15, wherein generating the expanded set of training data based on the iterative operations comprises determining the resource utilization of the synthetic system design based on compiling the synthetic system design.

EXAMPLE EMBODIMENT 20. The method of example embodiment 16, wherein training the machine learning model comprises training the machine learning model to predict the resource utilization metrics for a system design based on an aggregate count of lookup tables (LUTs), a granular count of LUTs based on a number of inputs that the LUTs are configured to receive, a count of LUT to flip-flop pairs, a count of flip-flop-to-LUT pairs, a bit allocation for random access memory (RAM) blocks, a bit allocation for digital signal processing (DSP) blocks, a count of input/output (I/O) pins, a count of interconnect resources, a count of varying length fan-out structures, or any combination thereof.

What is claimed is:

1. A system comprising:
a programmable integrated circuit device; and
a data processing system configured to execute instructions stored on a tangible, non-transitory, computer-readable medium to:
receive a system design for the programmable integrated circuit device;
generate a technology-mapped netlist based on synthesizing the system design;
determine, via a resource utilization model, a predicted resource utilization for the system design based on the technology-mapped netlist; and
generate a resource utilization report based on the predicted resource utilization.

2. The system of claim 1, comprising a model training system, wherein the model training system comprises:
processing resources; and
an additional tangible, non-transitory, computer-readable medium storing instructions that, when executed by the processing resources, cause the processing resources to generate synthetic training data to provide to the resource utilization model.

3. The system of claim 2, wherein the instructions stored on the additional tangible, non-transitory, computer-readable medium cause the processing resources of the model training system to:
receive a set of system designs for a plurality of programmable integrated circuit devices;
generate an expanded set of system designs based on combining design hierarchies in the set of system designs to generate synthetic system designs;
determine resource utilization metrics for each system design in the expanded set of system designs; and
provide the expanded set of system designs and corresponding resource utilization metrics to the resource utilization model to be used by the resource utilization model as training data during a training phase.

4. The system of claim 1, wherein the data processing system is configured to execute the instructions to:
receive an indication comprising one or more changes to the system design, an alternative programmable integrated circuit device for implementing the system design, a resource mix to be used to implement the system design on the programmable integrated circuit device, or any combination thereof; and
determine, via the resource utilization model, an additional predicted resource utilization based on the indication.

5. The system of claim 1, wherein the predicted resource utilization comprises an indication of an amount of programmable logic on the programmable integrated circuit device that is expected to be occupied by the system design.

6. The system of claim 1, wherein the resource utilization model is configured to determine the predicted resource utilization before fitting the technology-mapped netlist onto the programmable integrated circuit device.

7. The system of claim 1, wherein the resource utilization model is trained to determine resource utilization for multiple programmable integrated device circuit device types, including field programmable gate arrays (FPGAs) and application-specific integrated circuits (ASICs).

8. A non-transitory, computer-readable medium, comprising computer-readable instructions that, when executed by a data processing system, cause the data processing system to:
receive a system design for a programmable integrated circuit device;
generate a technology-mapped netlist for the system design; and
determine, via a resource utilization model, a predicted resource utilization for the system design based on the technology-mapped netlist, wherein the resource utilization model is configured to determine the predicted resource utilization before fitting the technology-mapped netlist onto the programmable integrated circuit device.

9. The non-transitory, computer-readable medium of claim 8, wherein the instructions cause the data processing system to generate a predicted resource utilization report comprising one or more resource utilization metrics based on the predicted resource utilization, and wherein the one or more resource utilization metrics comprise a predicted amount of programmable logic on the programmable integrated circuit device, a predicted count of a programmable logic circuit element on the programmable integrated circuit device, or any combination thereof.

10. The non-transitory, computer-readable medium of claim 8, wherein the instructions cause the data processing system to:
receive a set of system designs from a manufacturer library, wherein the set of system designs corresponds to actual training data;
generate an expanded set of system designs based on combining design hierarchies in the set of system designs, wherein the expanded set of system designs comprises synthetic training data and the actual training data;
determine resource utilization metrics for each system design in the expanded set of system designs; and
provide the expanded set of system designs and corresponding resource utilization metrics to the resource utilization model to be used by the resource utilization model during training.

11. The non-transitory, computer-readable medium of claim 10, wherein the resource utilization model is trained based on feature engineering to identify one or more features in the technology-mapped netlist based on a correlation between the one or more features and the resource utilization metrics for each system design in the expanded set of system designs.

12. The non-transitory, computer-readable medium of claim 8, wherein the instructions cause the data processing system to:
store the technology-mapped netlist in a data repository before fitting the technology-mapped netlist onto the programmable integrated circuit device; and
generate a predicted resource utilization report based on the predicted resource utilization for the system design before fitting the technology-mapped netlist onto the programmable integrated circuit device.

13. The non-transitory, computer-readable medium of claim 12, wherein the instructions cause the data processing system to:
generate a post-fit resource utilization report after fitting the technology-mapped netlist onto the programmable integrated circuit device, wherein the predicted resource utilization report and the post-fit resource utilization report include at least one common resource utilization metric, and wherein the at least one common resource utilization metric in the predicted resource utilization report is at least 95% accurate relative to the post-fit resource utilization report.

14. The non-transitory, computer-readable medium of claim 8, wherein fitting the technology-mapped netlist onto the programmable integrated circuit device corresponds to a greater timing cost than generating the technology-mapped netlist based on synthesizing the system design.

15. A method of training a machine learning model for predicting resource utilization metrics in a programmable integrated circuit device comprising:
receiving a set of training data comprising a plurality of actual system designs from a library;
generating an expanded set of training data comprising the plurality of actual system designs and a plurality of synthetic system designs based on operations comprising iteratively:
determining a count of system designs in the expanded set of training data;
based on the count of system designs in the expanded set of training data being less than or equal to a count threshold:
generating a synthetic system design;
assigning a resource utilization threshold to the synthetic system design;
in response to a determined resource utilization of the synthetic system design being less than the resource utilization threshold, iteratively adding design hierarchies to the synthetic system design until the determined resource utilization of the synthetic system design is greater than or equal to the resource utilization threshold; and
in response to the determined resource utilization of the synthetic system design being greater than or equal to the resource utilization threshold, adding the synthetic system design to the expanded set of training data; and
training the machine learning model to predict the resource utilization metrics for the programmable integrated circuit device based on the expanded set of training data.

16. The method of claim 15, comprising training the machine learning model based on the synthetic system designs in the expanded set of training data and validating the machine learning model on the plurality of actual system designs in the expanded set of training data.

17. The method of claim 15, wherein each actual system design in the set of training data comprises a plurality of design hierarchies, and wherein iteratively adding the design hierarchies to the synthetic system design comprises selecting a design hierarchy from the plurality of design hierarchies based on one or more resource utilization characteristics of the design hierarchy or selecting the design hierarchy from the plurality of design hierarchies based on a pseudo-random selection algorithm.

18. The method of claim 15, wherein each actual system design in the set of training data comprises a plurality of design hierarchies, wherein each design hierarchy in the plurality of design hierarchies is associated with a predetermined resource utilization metric, and wherein generating the expanded set of training data based on the iterative operations comprises determining the resource utilization of the synthetic system design based on summing the predetermined resource utilization metrics for each design hierarchy added to the synthetic system design.

19. The method of claim 15, wherein generating the expanded set of training data based on the iterative operations comprises determining the resource utilization of the synthetic system design based on compiling the synthetic system design.

20. The method of claim 16, wherein training the machine learning model comprises training the machine learning model to predict the resource utilization metrics for a system design based on an aggregate count of lookup tables (LUTs), a granular count of LUTs based on a number of inputs that the LUTs are configured to receive, a count of LUT to flip-flop pairs, a count of flip-flop-to-LUT pairs, a bit allocation for random access memory (RAM) blocks, a bit allocation for digital signal processing (DSP) blocks, a count of input/output (I/O) pins, a count of interconnect resources, a count of varying length fan-out structures, or any combination thereof.
